(19) United States
(12) Patent Application Publication
(10) Pub. No.: US 2023/0375635 A1
(43) Pub. Date: Nov. 23, 2023

(54) SYSTEM AND METHOD FOR BATTERY STATE OF HEALTH CHARACTERIZATION BASED ON ROUTE SEGMENTS

(71) Applicant: Hyliion Inc., Cedar Park, TX (US)

(72) Inventors: George James Noland, Sarver, PA (US); Ryan Wostarek, Pflugerville, TX (US); Joseph Collette, Georgetown, TX (US)

(21) Appl. No.: 18/316,432

(22) Filed: May 12, 2023

Related U.S. Application Data
(60) Provisional application No. 63/343,440, filed on May 18, 2022.

(51) Int. Cl. G01R 31/392; H02J 7/14; H02J 7/00; G01R 31/3835; G01R 31/367; G01R 31/389; G01R 31/374; G01C 21/34

(52) U.S. Cl. CPC G01R 31/392; H02J 7/1446; H02J 7/005; G01R 31/3835; G01R 31/367; G01R 31/389; G01R 31/374; G01C 21/3469

(57) ABSTRACT

A method for determining state of health of a battery on a vehicle comprises identifying a SOH testing segment on which the battery can be charged at a known charging rate for a time duration and determining an increase in voltage based on the charging rate, the time duration, an internal resistance of the battery, and/or a battery temperature differential over the time duration.

### BENEFIT CLAIM

This application claims the benefit under 35 U.S.C. § 119(e) of application 63/343,440, filed 18 May 2022, the entire contents of which are hereby incorporated by reference for all purposes as if fully set forth herein.

### BACKGROUND

### Field of the Disclosure

This disclosure relates generally to managing operation of hybrid drivetrains in vehicles and, more particularly, to battery State of Health (SOH) characterization for a battery installed in large vehicles configured for transporting cargo of different weights over routes of varying terrain.

### Description of the Related Art

Trucks are large, wheeled vehicles that can transport cargo over long distances. Trucks traditionally comprise a drivetrain with an internal combustion engine sized to provide enough power to drive the truck and any cargo over long distances and on roads of varying grades. The truck is either configured with an integrated cargo compartment (often referred to as a box truck) or is configured for coupling to a trailer comprising the cargo compartment (wherein the combination may be referred to as a tractor-trailer). Trucks are used to transport large volumes of cargo on land, wherein the combination of the truck and a trailer can weigh between 30,000 pounds empty up to 140,000 pounds for a tandem loaded trailer. Trucks may be used on roads with improved surfaces such as highways and in urban areas but may also be used on roads with unimproved surfaces such as gravel and sand.

State of charge (SOC) of a battery refers to the ratio of charge of a battery relative to a total charge capacity. SOC is typically expressed as a percentage, wherein 100% SOC means the battery is fully charged and 0% means the battery is completely discharged.

### SUMMARY

Embodiments described herein may use predictive terrain knowledge to estimate HV battery SOH using active charge/discharge waveforms.

Vehicles described herein may comprise a chassis with a drivetrain comprising an engine, a battery, one or more motor/generators (M/G) connected to the battery and a controller executing instructions to manage performance of the drivetrain. Each M/G may operate as a motor to receive electric power from the battery and generate rotational power and may operate as a generator to receive rotational power from the engine or a drive axle and generate electric power to charge the battery.

Vehicles with hybrid drivetrains may contain an engine for generating rotational power supplied to a first motor for supplying electric power to a first drive axle and a motor operable as a motor for generating rotational power supplied to a second drive axle and operable as a generator for generating electric power from rotational power received from the second drive axle.

Vehicles with parallel hybrid drivetrains may contain an engine for generating rotational power supplied to a first drive axle and an electric motor operating as a motor for generating rotational power supplied to a second drive axle and operating as a generator for generating electric power from rotational power received from the second drive axle.

Embodiments disclosed herein include a method to calculate or determine battery SOH using active charge/discharge waveforms.

Embodiments may be directed to a method for monitoring state of health (SOH) of a battery in a vehicle comprising a drivetrain with the battery, an engine and a motor/generator (M/G) coupled to the engine and operable as a generator to convert the rotational power from the engine to electrical power for charging the battery. The method comprises determining a route for the vehicle to travel, determining a SOH testing segment on the route, the SOH testing segment having a distance and a grade, and selecting a state of health (SOH) test comprising a charging rate or a discharging rate for supplying electric power to the battery and a time duration for supplying the electric power. As the vehicle travels on the SOH testing segment, embodiments determine a state of charge (SOC) of the battery, measure an internal resistance of the battery, measure a starting battery temperature at the start of a time duration, operate the M/G as a generator to supply the electric power to the battery at the charging rate or operate the M/G as a motor for receiving the electric power from the battery at the discharging rate for the time duration. At the end of the time duration, embodiments measure an end battery temperature, calculate a battery temperature differential for the time duration and determine a voltage increase or voltage decrease based on the battery temperature differential. Embodiments determine a state of health of the battery corresponding to the voltage increase or voltage decrease and the SOC of the battery.

In some embodiments, the method comprises storing, in memory, a data structure comprising a plurality of battery capacity profile tables, wherein each battery capacity profile table contains stored values for a charging rate, an internal resistance of the battery, a SOC of the battery and a battery temperature differential corresponding and a calculated voltage increase corresponding to the stored values; and comparing the supplied charging rate, the measured internal resistance of the battery, the calculated battery temperature differential, and the SOC of the battery with the stored values in a battery capacity profile table of the plurality of battery capacity profile tables to determine the voltage increase based on the calculated voltage increase contained in the battery capacity profile table from the plurality of battery capacity profile tables.

In some embodiments, measuring the internal resistance of the battery comprises operating the M/G as a generator for generating electric power, supplying the electric power to the battery according to a reference waveform, measuring the voltage increase, calculating the internal resistance of the battery based on the voltage increase for the reference waveform and storing the internal resistance of the battery in the memory.

In some embodiments, a reference waveform comprises a series of pulses of the supplied electric power. In some embodiments, the charging rate is constant.

In some embodiments, the method comprises determining a prep segment preceding the SOH testing segment and operating the vehicle in the prep segment to perform one of: cooling the battery, whereby the starting battery temperature is less than a maximum SOH testing battery temperature; warming the battery, whereby the starting battery temperature is greater than a minimum SOH testing battery temperature; charging the battery, whereby the battery SOC is greater than a minimum SOH testing battery SOC; and discharging the battery, whereby the battery SOC is less than a maximum SOH testing battery SOC.

In some embodiments, determining a SOH testing segment on the route comprises receiving a set of route data corresponding to the route, determining a route start point and a route end point for the set of route data, identifying a plurality of segments and selecting a SOH testing segment from the plurality of segments based on a set of vehicle characteristics and a set of segment characteristics. Identifying the plurality of segments comprises identifying a set of uphill segments in the route data, wherein each uphill segment is defined by a grade that exceeds a minimum grade threshold and a segment distance that is greater than a defined minimum distance, identifying a set of downhill segments in the route data, wherein each downhill segment is defined by an average grade that is less than a defined downhill threshold and a segment distance that is greater than the defined minimum distance and identifying a set of flat segments in the route data, wherein each flat segment is defined as a segment determined to not be an uphill segment or a downhill segment and a segment distance that is greater than a defined minimum distance.

In some embodiments, determining a SOH testing segment based on a set of vehicle characteristics and a set of segment characteristics comprises determining a performance plan for the vehicle, the performance plan comprising a set of drivetrain configuration instructions and predicted values of a set of operating parameters of the vehicle for each segment of the plurality of segments, wherein the predicted values comprise a predicted starting battery SOC and a predicted starting battery temperature. Determining a performance plan further comprises, for each segment, determining a predicted starting battery SOC, wherein each SOH testing segment has a predicted starting battery SOC in a starting battery SOC range, determining a predicted starting battery temperature, wherein each SOH testing segment has a predicted starting battery temperature in a starting battery temperature range, determining a segment distance, wherein each SOH testing segment has a segment distance greater than a minimum SOH testing distance, and determining a grade, wherein each SOH testing segment has a grade that does not exceed a minimum SOH testing grade or a maximum SOH testing grade.

In some embodiments, the starting battery SOC range is between 20% and 80% and the starting battery temperature range is between 20-35 C. In some embodiments, the starting battery SOC range is between 40% and 60% and the starting battery temperature range is between 25-30 C.

### BRIEF DESCRIPTION OF THE DRAWINGS

For a more complete understanding of the present invention and its features and advantages, reference is now made to the following description, taken in conjunction with the accompanying drawings, in which:

FIG. 1 depicts a block diagram of a system for determining a configuration of a drivetrain in a vehicle and communicating a performance plan for controlling the vehicle;

FIG. 2 depicts a data structure containing route data representing a route;

FIG. 3 depicts a data structure containing segment information determined by compressing route data points for a route;

FIG. 4 depicts a flow diagram illustrating a portion of a method for compressing route data into a set of linearized segments;

FIG. 5 depicts a data structure containing drivetrain configuration information;

FIG. 6 depicts a data structure containing a performance plan for a vehicle;

FIG. 7 is a flow diagram of one embodiment of a method for selecting segments on a route for State of Health (SOH) testing;

FIG. 8 depicts a data structure containing predicted voltage increase values corresponding to battery capacity profiles; and

FIG. 9 depicts a data structure containing performance plan information.

### DESCRIPTION OF PARTICULAR EMBODIMENT(S)

In the following description, details are set forth by way of example to facilitate discussion of the disclosed subject matter. It should be apparent to a person of ordinary skill in the field, however, that the disclosed embodiments are exemplary and not exhaustive of all possible embodiments.

For the purposes of this disclosure, embodiments are described as they pertain to a large, wheeled vehicle with a drivetrain comprising an engine, a battery, one or more motor/generators (M/Gs) configurable as a motor or a generator, and a controller. Embodiments may also pertain to other wheeled vehicles with more or fewer axles and other vehicles including, for example, box trucks, buses, trucks, tractors, and/or tractor/trailer combinations. As used herein, the term battery may refer to a single battery or a plurality of batteries (often referred to as a “battery pack”) operating as a single unit.

Knowing the SOH (State of Health) of a battery is important, especially for calculations involving the state of the capacity and resistance to degradation of the cells. Embodiments may determine the SOH of a battery by operating the electric motor to charge the battery, measuring the rise in battery temperature and using the rise in battery temperature and the internal resistance of the battery to determine the SOH.

A battery State of Charge (SOC) calculation typically depends on having an accurate slow rate capacity estimate for Coloumb Counting. Charge and discharge current limit algorithms may depend on a relatively accurate battery ohmic resistance.

Embodiments described herein may use predictive terrain knowledge to determine there is freedom to charge or discharge a battery at any desired amplitude within certain bounds to determine the state of health of the battery. For example, embodiments may analyze route data and determine there will be a segment having a segment distance of 10 miles with very flat terrain ahead, where a battery in the vehicle can be charged for an extended period of time. As the vehicle travels over the segment, a controller executes a set of drivetrain configuration instructions to operate the M/G as a generator to charge the battery for a time duration. The controller may communicate with sensors to determine a rise in the battery temperature and determine, based on the charging rate, the internal resistance of the battery and the battery temperature increase, an increase in the battery voltage. The controller may use the rise in voltage to update the SOH of the battery and use the updated SOH of the battery for more accurate calculations such as battery SOC and the operating range of the vehicle.

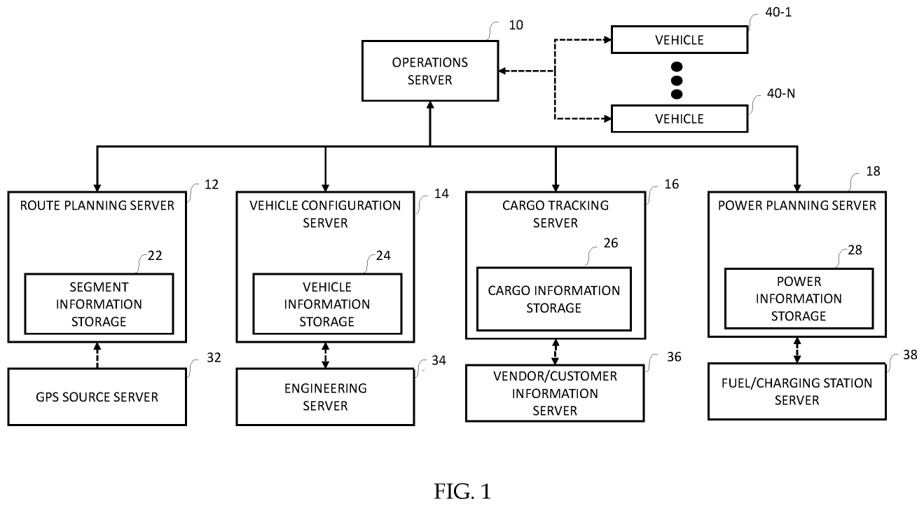

Particular embodiments may be best understood by reference to FIGS. 1-9, wherein like numbers are used to indicate like and corresponding parts.

System Overview

Turning now to the drawings, a system for managing operation of a drivetrain in a vehicle 40 may include an operations server 10 communicatively coupled to route planning server 12, vehicle configuration server 14, cargo tracking server 16 and power planning server 18. Operations server 10 may also communicate with one or more vehicles 40 to receive information about each vehicle 40 and/or send instructions to each vehicle 40 to adjust an operating parameter based on reducing a cost to operate the vehicle 40, reduce emissions by the vehicle 40 or for increasing a service life of the vehicle 40.

Operations server 10 may store information associated with a plurality of vehicles 40 used to transport cargo. Operations server 10 may also store information associated with operations of a business, including managing costs associated with transporting cargo and managing the delivery of cargo.

Route planning server 12 may communicate with operations server 10 to get route planning information and route data about one or more routes for a vehicle 40. The route planning information may include a route start point and a route end point for the vehicle 40, speed limit information for each possible route, traffic information for each possible route, weather information for each possible route and toll road information. In some embodiments, route information may include information about fuel station locations, charging location or other stopover locations on the route. In some situations, a route start point may be a location such as a central warehouse and a route end point may be a retail location. Route planning server 12 uses route planning information and route data to determine one or more routes over which a vehicle 40 may travel from the route start point to the route end point. Route planning server 12 may communicate with a GPS source server 32 to retrieve route data, analyze the route data and store the analyzed route data in segment information storage 22. Route planning server 12 may communicate results of any analysis to operations server 10 and/or vehicle 40.

Vehicle configuration server 14 may communicate with operations server 10, engineering server 34 and vehicle 40 to get vehicle configuration information about vehicle 40. Vehicle configuration server 14 may communicate with engineering server 34 to get operating parameters for a particular vehicle 40 or a type of vehicle 40. For example, engineering server 34 may contain information about an engine output parameter for a type of engine, information about a service life for an engine or motor and engine emission levels for various operating conditions. Vehicle configuration server 14 may communicate with a particular vehicle 40 to get information about a drivetrain configuration in which vehicle 40 is operating or can operate. In some embodiments, when a vehicle 40 starts, it communicates present values for a set of operating parameters to vehicle configuration server 14. Present values for the operating parameters may include parameters that might not change, such as a vehicle base weight and a chassis type and may also include values for operating parameters that change such as a fuel level and a battery state of charge. Vehicle configuration information may be stored in vehicle information storage 24.

Cargo tracking server 16 may communicate cargo load information to operations server 10. Cargo load information may include the type of cargo, a weight, any information specific to the cargo load (e.g., if a cargo load requires refrigeration, if there is hazardous material, if the cargo load must be delivered by a deadline, etc.). In some embodiments, a user may enter information for storing in cargo information storage 26. In some embodiments, cargo tracking server 16 may communicate over a network with vendor/customer information servers 36 associated with vendors, merchants or other external parties to get cargo load information. Cargo tracking server 16 may store cargo load information in cargo information storage 26.

Power planning server 18 communicates with operations server 10 to determine values for operating parameters associated with operating vehicle 40 and may communicate with fuel stations and charging stations to identify one or more locations where fuel may or should be acquired. In some embodiments, power planning server 18 communicates over a network with fuel/charging station servers 38 associated with third parties (external sources) or associated with facilities (internal sources) to get fuel/charging information. Power planning server 18 may get information about fuel cost, a wait time for availability of a pump, a number of pumps at a fuel station, an electric power cost (including variations in charging cost due to peak demand, off demand, holiday and weekday or weekend rates), a wait time for availability for a charging station, a number of charging stations, a rate at which charging can occur and store the information in power information storage 28.

Operations server 10 may communicate with other systems as well. For example, operations server 10 may communicate with a warehouse server to determine how much time a vehicle 40 stays at the warehouse, communicate with a traffic server to identify traffic or traffic patterns, communicate with a weather server to get updates on weather, and communicate with a satellite imagery server to get information about a route.

In some embodiments, operations server 10 may communicate instructions to one or more of route planning server 12, vehicle configuration server 14, cargo tracking server 16, power planning server 18, GPS source server 32, engineering server 34, vendor/customer information server 36 and fuel/charging station server 38 to send information and operations server 10 may perform calculations and execute processes for determining values including target values and/or predicted values for a set of operating parameters for managing operation of a drivetrain in vehicle 40 and communicate the values to vehicle 40. In some embodiments, two or more of operations server 10, route planning server 12, vehicle configuration server 14, cargo tracking server 16, power planning server 18, GPS source server 32, engineering server 34, vendor/customer information server 36, fuel/charging station server 38, vehicle information storage 24, cargo information storage 26 and power information storage 28 may form part of the same server.

In some embodiments, operations server 10 may communicate instructions to one or more of route planning server 12, vehicle configuration server 14, cargo tracking server 16, power planning server 18, GPS source server 32, engineering server 34, vendor/customer information server 36 and fuel/charging station server 38 to perform calculations, execute processes for determining a set of operating parameters for controlling one or more vehicles 40, and communicate the set of operating parameters for controlling one or more vehicles 40 to operations server 10, wherein operations server 10 communicates a set of operating parameters to each of the one or more vehicles 40.

System 100 may communicate with a single vehicle 40 or a fleet of vehicles 40 to manage operation of a drivetrain in vehicle 40 over a route or set of routes. A fleet may be as small as two vehicles 40 but fleets may also have more than a hundred vehicles 40.

As described herein, managing operation of a drivetrain in a vehicle 40 may include communicating a set of drivetrain configuration instructions and values for a set of operating parameters of the vehicle 40. More effective operation of the drivetrain may be possible with improved understanding of the state of health (SOH) of the battery.

Determining State of Health in a Vehicle

Determining SOH and SOC of a battery in a controlled setting may be relatively straightforward. For example, the battery may be rested and cooled or warmed to an optimum temperature, a constant current may be applied over an extended time and a voltage may be measured across the terminals. Determining SOH of a battery in vehicle 40 may be limited by the operation of the drivetrain in the vehicle 40. For example, SOH testing requires controlled conditions, but if vehicle 40 starts traveling downhill and begins operating in a regenerative mode, the unexpected surge in electric power to the battery may interfere with SOH testing.

To overcome these shortcomings, embodiments manage operation of the drivetrain in vehicle 40 to accommodate SOH testing.

Embodiments use technology to analyze the route on which vehicle 40 is going to travel to identify a plurality of segments and then analyze each segment to determine if the segment is available for SOH testing. Embodiments analyze each segment based on a set of segment characteristics and a set of vehicle characteristics. Embodiments communicate a performance plan to vehicle 40 including a set of drivetrain configuration instructions with values for operating parameters for the vehicle 40 to enable SOH testing on one or more SOH testing segments.

A method for managing operation of a drivetrain in vehicle 40 begins when a route for vehicle 40 is determined. In some embodiments, operations server 10 communicates with cargo server 16 and route planning server 12 to determine a route between a route start point and a route end point.

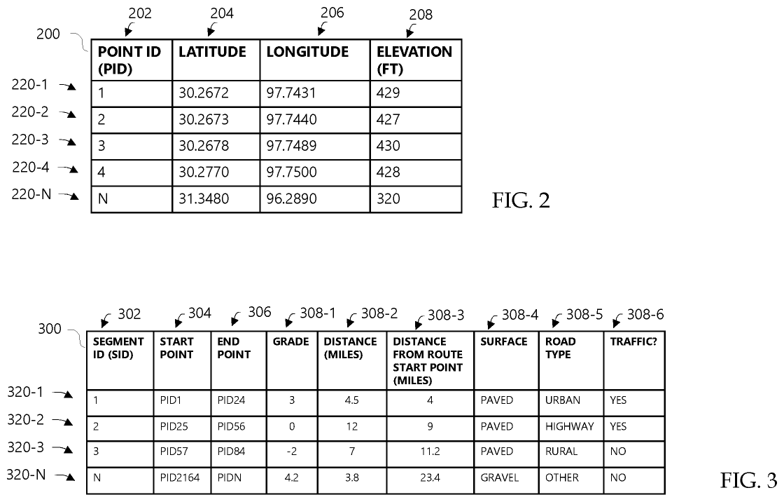

FIG. 2 depicts a data structure 200 comprising a plurality of route data points 220-1 to 220-N. Each route data point 220 may have a route data point identifier (ID) 202 and contain values for a latitude 204, a longitude 206 and an elevation 208. Route data points 220 may be retrieved from an outside source (such as GPS source server 32) and contain a large plurality of route data points. In one sample 25-mile route, the number of route data points 220 exceeded 4000 route data points 220 such that calculations quickly become difficult or expensive to perform.

Route Data is Difficult to Use

Using route data with thousands of route data points 220 in calculations to determine a control strategy or performance plan for vehicles 40 is computationally expensive. Furthermore, there may be variations or inconsistencies in route data points 220, making the route difficult to analyze. For example, in some embodiments, elevation data from the U.S. Geological Service may be associated with each coordinate. USGS elevation data along roads is noisy and there are places where elevations are clearly incorrect, as the resulting grade of the road would exceed any actual grade found on roads. For example, referring to data structure 200, route data point 220-3 identified as point ID_3 has a higher elevation than adjacent route data points 220-2 and 220-4 (and has the highest overall elevation (e.g., 430 ft) for the four data points 220-1 to 220-N, and route data point 220-2 has a lower elevation than adjacent route data points 220-1 and 220-3. However, due to tolerances in measuring route data points 220, any of route data points 220-1 to 220-N may be the highest or the lowest in that section of the route. In some embodiments, route data points 220 that result in such grades may be adjusted such that all the resulting grades between points are reasonable.

Route Compression into Linearized Segments

Embodiments may compress route data into linearized segments, wherein each segment has a distance and grade between a start point and an end point. Segments in a route may vary in distance. Thus, the number of points corresponding to a segment may also vary.

A method for compressing a route into linearized segments may comprise analyzing route data points (such as route data points 220 in data structure 200) to identify uphill, downhill and flat segments.

### Determining Uphill/Downhill Segments

Uphill segments are defined as segments of a route over which the average grade exceeds a minimum grade threshold and the segment spans a distance greater than a defined minimum distance.

Downhill segments are defined as segments of a route over which the average grade is less than a defined downhill threshold and the segment spans a distance greater than a defined minimum distance.

Starting at the first route point (e.g. point ID 1 in data structure 200) at the beginning of the route, embodiments analyze adjacent route data points 220 for a potential start of an uphill segment. Any grade between adjacent route data points 220 that exceeds the minimum grade threshold for an uphill segment is a potential start of an uphill segment. A potential uphill is investigated to determine if it meets the minimum distance and grade requirements. Exceptions are identified for short segments between two route data points 220 where the grade falls below the minimum grade threshold. If the number of exceptions does not exceed a defined maximum, the investigation of this hill continues. If the thresholds for grade and distance are satisfied and the allowed exception limit is not exceeded, the segment is identified as an uphill segment. For the first segment, the segment start point is the same as the first route data point 220-1.

A segment end point of the confirmed uphill segment needs to be identified to complete the uphill segment. This is done by finding a consecutive span of the route where the average grade requirement is less than the minimum grade threshold. Once the end of an uphill segment has been determined, segment information including a segment identifier and segment characteristics such as a segment start point, a segment end point, a grade and a distance may be stored in segment information storage 22 or other memory accessible by operations server 10 and the search process continues from the route data point 220 after the last route data point 220 identified in the previous segment.

If route data points 220 for a potential uphill/downhill segment fail to meet the requirements, route analysis continues from the route data point 220 at which the potential uphill/downhill segment failed to meet the requirements.

### Determining Flat Segments

Flat segments may be defined as the segments of the route determined to not be an uphill or downhill segment.

### Initial Flat Segment

An initial flat segment may be determined by starting at the first route data point 220-1 at the beginning of the route and checking whether the current route data point 220 on the path is part of an uphill segment or downhill segment.

If the current route data point 220 is not part of an uphill segment or downhill segment, then the initial flat segment is determined by identifying the closest uphill segment or downhill segment start point and selecting that route data point 220 as the end point for the flat segment.

### Subsequent Flat Segments

Embodiments may identify a flat segment based on an uphill segment or downhill segment determined from the start of the route that is beyond the last route data point 220 of the last flat segment found.

The uphill segment or downhill segment is based on the shortest distance along the path to the start of the uphill or downhill segment. The last route data point 220 of an uphill segment or a downhill segment may be identified as the start point of a flat segment if the next route data point 220 on the route is not part of an uphill segment or downhill segment. Each flat segment spans from the end point of an uphill segment or downhill segment to the start point of the next uphill segment or downhill segment. Route analysis continues using the end point of each uphill segment or downhill segment whose start point was used as the end point of the last flat segment found. The process is repeated until all the flat segments between uphill/downhill segments are found.

### Terminal Flat Segment

Embodiments determine whether the last route data point 220 on the route is part of an uphill segment or downhill segment. If it is not part of an uphill segment or downhill segment, embodiments search back from the end point for the uphill segment or downhill segment whose distance is furthest from the beginning of the route. The end point on the uphill segment or downhill segment found above becomes the start point of the terminal flat segment. The last route data point 220 is the end point of the terminal flat segment.

Each flat segment is saved with the start and end points of the segment, distance from the start of the route, the grade of the flat segment and the flat segment span distance.

FIG. 3 depicts a data structure 300 comprising segment information for a plurality of segments 320 based on route points 220 from data structure 200. Data structure 300 may contain segment information derived from thousands of route points 220. Data structure 300 may contain other information as well. For example, data structure 300 may contain, for each segment 320, a segment identifier (ID) 302, segment start point 304 and segment end point 306. Furthermore, data structure 300 may include segment characteristics 308 including grade 308-1, segment distance 308-2, distance from the route start point 308-3, segment surface type 308-4, segment road type 308-5, traffic information 308-6 and may include other segment characteristics including but not limited to speed limit information, weather information and toll information. For the example mentioned with respect to FIG. 2, embodiments analyzed 4082 route data points corresponding to a sample 25-mile route and developed a data structure 300 containing 39 segments representing the 25-mile route, resulting in a 99% decrease in the number of calculations needed to perform additional processing.

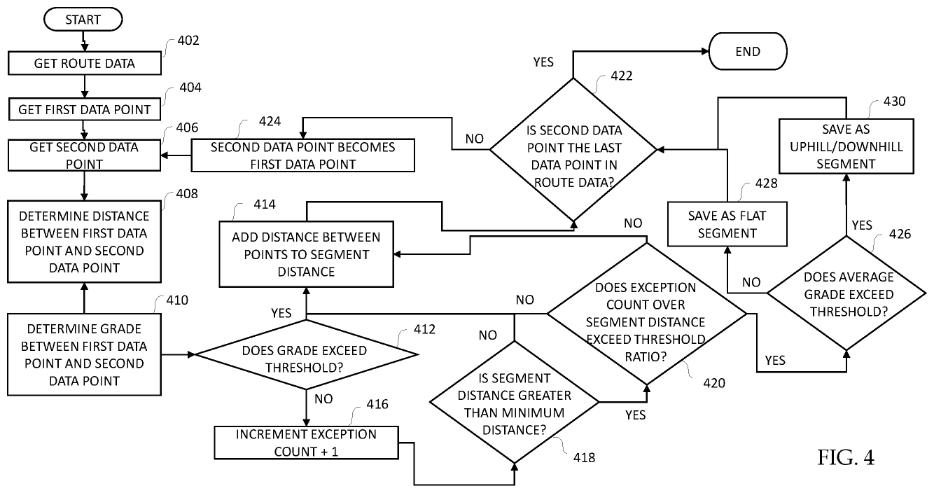

FIG. 4 depicts a flow diagram 400 of one method for compressing a plurality of route data points into a plurality of segments 320. Flow diagram 400 is described as it pertains to finding an uphill segment but the steps may be performed for finding a downhill segment.

At step 402, embodiments get route data. Route data may be collected in various ways. For example, route data may be retrieved from an external or third-party source such as GPS source server 32, may be collected from vehicles 40 traveling along a route or by satellite imagery. Route data may include coordinates corresponding to route data points 220 along the route. In some embodiments, route data may include only values for latitude 204 and longitude 206 for each route data point 220. In some embodiments, route data may include values for latitude 204, longitude 206 and elevation 208 for each route data point 220. In some embodiments, route data may include route information such as a speed limit, tolls and other fees. In some embodiments, route data may include route information such as weather conditions, road conditions or traffic conditions such as a current average speed of other vehicles 40 currently traveling along the route, as well as other factors that could affect the time needed for a vehicle 40 to travel along the route.

At step 404, embodiments identify a first route data point 220 (e.g., route data point PID_1 referred to in row 220-1). The first route data point 220 may be determined to be the first segment start point.

At step 406, embodiments identify a second route data point 220 (e.g., route data point PID_2 referred to in row 220-2) adjacent to the first route data point 220.

At step 408, embodiments determine a distance between the first route data point 220 and the second route data point 220.

At step 410, embodiments determine a grade between the first route point 220 and the second route point 220. Embodiments may determine a change in elevation between the first point 220 and the second route data point 220 and divide the change in elevation by the distance between the first route data point 220 and the second route data point 220 to determine the grade between the first route point 220 and the second route data point 220.

At step 412, embodiments determine if the grade between the first route point 220 and the second route point 220 exceeds a grade threshold. A grade threshold for an uphill segment 320 may be a positive value, wherein a grade between two adjacent route data points 220 that is greater than the positive value would exceed the grade threshold. For example, in some embodiments, the grade threshold for an uphill segment 320 may comprise a grade threshold of at least +0.25, at least +0.5, at least +0.75, at least +1.0, at least +1.5, at least +2.0, at least +2.5, or even at least +3.0 or greater. A grade threshold for a downhill segment 320 may be a negative value, wherein a grade between two adjacent route data points 220 that is less than the negative value would exceed a grade threshold. For example, in some embodiments, the grade threshold for a downhill segment 320 may comprise a grade threshold of at least −0.25, at least −0.5, at least −0.75, at least −1.0, at least −1.5, at least −2.0, at least −2.5, or even at least −3.0 or greater.

At step 414, if the grade between the first route data point 220 and the second route data point 220 exceeds the grade threshold, the distance between the first route point 220 and the second route data point 220 is added to the segment distance 308.

If the grade between the first route data point 220 and the second route data point 220 does not exceed the grade threshold, then the first route data point 220 might be the last route data point 220 for the segment 320. To determine if the first route data point 220 is the last route data point 220 for the segment 320, embodiments determine if the grade between the first route data point 220 and the second route data point 220 represents an exception or is part of a transition to a new segment 320. At step 416, embodiments increment the exception count and at step 418, embodiments determine if the segment distance 308 is greater than a minimum distance.

If the segment distance is not greater than a minimum distance, the distance between the first route data point 220 and the second route data point 220 is added to the segment distance 308-2 at step 414. This may prevent embodiments from concluding that a segment 320 has ended based on one or two variations in route data points 220 early in the segment 320.

If the segment distance is greater than a minimum distance, then at step 420 embodiments determine if the exception count exceeds a threshold count. In some embodiments, the exception threshold count is calculated as a ratio of the number of exceptions relative to the segment distance. In some embodiments, exceeding an exception threshold count may cause additional processing. For example, a large number of exceptions may be allowed if the average grade for a segment still exceeds a grade threshold.

If the exception count for a segment distance does not exceed a threshold count, the distance between the first route data point 220 and the second route data point 220 is added to the segment distance at step 414.

At step 422, embodiments determine if the second route data point 220 is the last point in the route data.

If the second route data point 220 is the last route data point 220 in the route data, then the method ends.

Referring to step 420, if the exception count for a segment distance exceeds a threshold count, the distance between the first route data point 220 and the second route data point 220 is not added to the segment distance at step 414. Embodiments may determine a last route data point 220 for a segment 320 based on the segment distance associated with a route data point 220 associated with the segment distance.

At step 426, if the exception count for a segment distance exceeds a threshold count such that embodiments know the segment start point and the segment end point, embodiments determine an average grade for the segment 320. Embodiments may use the segment start point and the segment end point to determine the segment distance and may calculate the grade between the segment start point and the segment end point. In some embodiments, a linear best fit approximation is calculated using all the route data points 220 associated with segment 320 (including any exceptions). In some embodiments, a linear best fit approximation is calculated using the route data points 220 associated with a segment 320 (minus any exceptions). At step 426, embodiments may also determine if the average grade for segment 320 exceeds a grade threshold.

At step 428, if the average grade for the segment 320 does not exceed a grade threshold, the segment 320 is saved as a flat segment 320.

At step 430, if the average grade for the segment 320 exceeds a grade threshold, the segment 320 is saved as an uphill segment 320 (if the average grade is greater than a positive grade threshold value associated with an uphill segment 320) or a downhill segment 320 (if the average grade is less than a negative grade threshold value associated with a downhill segment 320).

Embodiments may repeat steps 406-430 until all route data has been analyzed and compressed into linearized segments 320 that are either uphill segments 320 (with a positive grade greater than a threshold grade), downhill segments 320 (with a negative grade less than a threshold grade) or flat segments 320 with a grade less than the threshold grade for uphill segments 320 and greater than the threshold grade for downhill segments 320. Further, in some embodiments, the analyzed route data for the linearized segments 320 may be stored in the segment information storage 22 by the route planning server 12.

Vehicles May have Different Drivetrain Configurations

Segment information may be the same for all vehicles 40 traveling on the same segment 320. However, different vehicles 40 traveling on the same segment 320 may have different drivetrain configurations and different cargo weights.

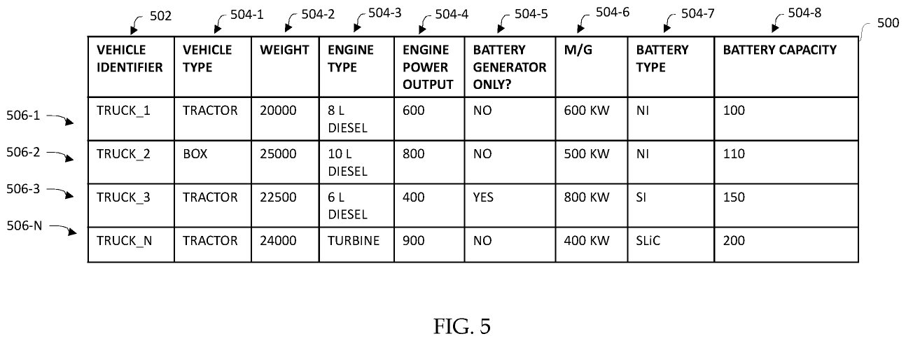

FIG. 5 is a data structure 500 for a plurality of vehicles 40, wherein data structure 500 depicts example vehicle drivetrain configuration information in table format. As depicted in FIG. 5, data structure 500 may include, for each vehicle 40 of a plurality of vehicles 40, vehicle drivetrain configuration information including a vehicle identifier 502 and vehicle characteristics 504 including a vehicle type 504-1, a gross weight 504-2, an engine type 504-3, an engine power output 504-4, an indication if the engine is to be used for electric power generation only 504-5, a motor power capacity 504-6, motor information 504-7, battery type 504-8 and battery charge capacity 504-9, and may include other vehicle drivetrain configuration information as well.

Vehicle type column 504-1 contains information for a characteristic of a type of vehicle 40, such as whether the vehicle 40 is a tractor, a box truck, a bus, a tractor/trailer combination, or some other type of vehicle 40. Weight column 504-2 contains characteristic information about the gross weight of vehicle 40. In some embodiments, weight column 504-2 may account for the gross weight of a trailer and/or a known cargo load. Engine type column 504-3 contains characteristic information on a type of engine installed in vehicle 40. Examples of engine types include an internal combustion (IC) engine (also referred to as an ICE) that may be configured to operate using gasoline, diesel, natural gas (NG) including compressed natural gas (CNG), liquid natural gas (LNG) and renewable natural gas (RNG), and other types of engine including, but not limited to, gas turbines and fuel cells, which may operate on hydrogen, natural gas, propane or some other fuel source. Engine power output column 504-4 contains characteristic information about how much power can be supplied by the engine type provided in engine type column 504-1. Battery generator column 504-5 contains characteristic information about whether vehicle 40 is configured with an engine used for generating electric power only or whether the engine may be used to directly provide rotational power to one or more axles to drive vehicle 40. M/G column 504-6 contains characteristic information about a motor/generator (M/G) installed in each vehicle 40. Battery type column 504-7 and battery charge capacity column 504-8 contain characteristic information about what type of battery is installed in each vehicle 40 and a battery capacity for the battery. Battery characteristic information may include other information, such as battery chemistry, the number of batteries, and values for the operating limits of a battery and other operating parameters. Battery characteristic information may include battery capacity and a state of charge (SOC) for a battery, represented as a percentage of the battery capacity.

Performance Plans Manage Operation of a Drivetrain

Embodiments may determine a performance plan for managing operation of the drivetrain of a vehicle 40. A performance plan may include a set of drivetrain configuration instructions and values for operating parameters of a drivetrain, including whether the drivetrain should operate using battery power, operate an engine to charge the battery, operate in regenerative mode to charge the battery, operate the engine without the battery and operate to cool the battery.

In some embodiments, a performance plan for managing operation of a drivetrain in a vehicle 40 may include a set of drivetrain configuration instructions and target values for a set of operating parameters based on one or more of reducing operating cost of the vehicle, reducing emissions caused by operating the vehicle 40 and extending the service life for the vehicle 40.

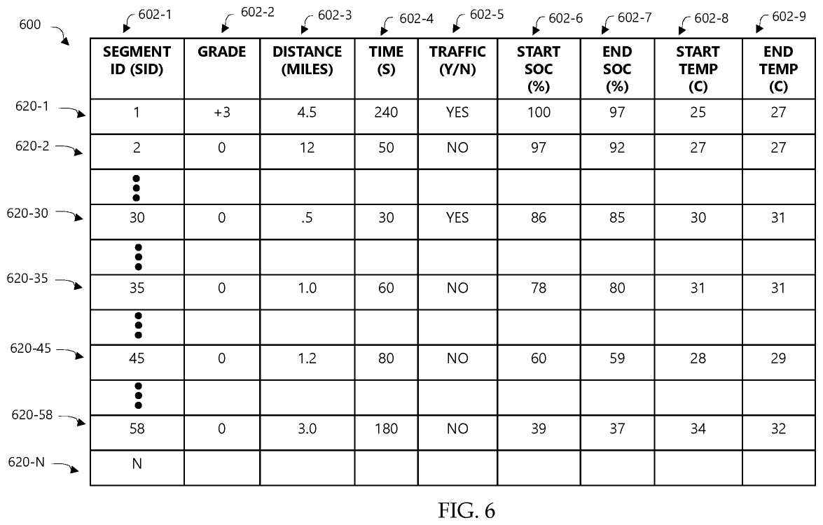

Referring to FIG. 6, data structure 600 contains columns 602 with drivetrain configuration information and values for operating parameters for a drivetrain in vehicle 40 for each segment 620. Information contained in data structure 600 may be communicated to vehicle 40 as part of a performance plan. Portions of data structure 600 may be based on information in data structure 300 described above. For example, segment ID column 602-1 contains segment identification based on segment ID column 302-1, wherein segment identifier SID_1 is the same for data structures 300 and 600. Data structure 600 contains segment characteristic information such as a grade in grade column 602-2, a segment distance in distance column 602-3, and a predicted time duration needed to travel the segment in time column 602-4. Traffic information column 602-5 contains an indication of the presence (or lack thereof) of traffic on each segment 620. Data structure 600 contains vehicle characteristic information. For example, start SOC column 602-6 may contain a present value of the starting battery SOC or may contain a target starting battery SOC (e.g., 50%) or a starting battery SOC range (40-60%) for each segment 620, end SOC column 602-7 may contain a present value or a predicted value of the end SOC for the battery on each segment 620, start temperature column 602-8 may contain a present value of the battery temperature or may contain a target starting battery temperature (e.g., 25 C), a maximum starting battery temperature (e.g., 30 C), a minimum starting battery temperature (e.g., 15 C) or a starting battery temperature range (e.g., 15-30 C) for each segment 620 and end temperature column 602-9 may contain a measured value or a predicted value of the battery temperature at the end of each segment 620.

Performance Plan Modification

A performance plan may be modified to accommodate actual driving conditions. For example, route information may include speed limit information indicating a speed limit over a route may be 65 miles per hour, but vehicle 40 may be traveling over the route at 45 miles per hour because the driver does not want to travel at 65 miles per hour (there may be bad weather, poor visibility, an accident, road maintenance, etc.) Embodiments may communicate a performance plan with a set of drivetrain configuration instructions and target values for a set of operating parameters for the vehicle 40 based on the vehicle speed, but the set of drivetrain configuration instructions do not include instructions to accelerate the vehicle 40.

A performance plan may need to be modified. For example, operations server 10 may communicate with engineering server 24 to get characteristic information about a type of battery in a particular vehicle 40, communicate with that vehicle 40 to determine a present value for the SOC, calculate a predicted starting SOC for a segment 620 and use vehicle characteristics and segment characteristics to predict a value for the SOC at the end of the segment. Embodiments may then use the end values for predicting start and end values of operating parameters in a subsequent segment. If the measured end SOC does not equal the predicted end SOC, the performance plan may need to be modified to ensure vehicle 40 is able to complete the route. Battery temperature, fuel level, engine efficiency and M/G efficiency are other examples of vehicle characteristic information that operations server 10 may analyze to determine a performance plan needs to be modified.

Battery Capacity Degrades Over Time

Referring briefly to battery capacity column 504-8 in FIG. 5, a battery installed in vehicle 40 has a battery capacity, wherein battery capacity refers to the amount of electrical energy the battery can store. As the battery ages, the battery capacity decreases. Battery capacity degradation depends on several factors, including time, the concentration of electrolyte, the number of cycles, the depth of discharge/charge for a cycle, etc. For example, a metal in a battery may corrode or get used up over time, regardless of whether the battery is being used. Furthermore, large charge/discharge cycles generate heat that may break down the electrolyte. As the battery capacity decreases, the rate at which battery temperature increases relative to the rate at which electrical power is supplied to the battery will also increase.

Battery Capacity Profile

The relationship between the rate at which battery temperature increases relative to the charging rate (the rate at which electrical power is supplied to the battery) may be referred to as a battery capacity profile. Graphically, a battery capacity profile may be linear such that battery temperature increases proportionally to the charging rate. In some embodiments, a data structure stored in memory in vehicle 40 or operations server 10 may contain values corresponding to a battery capacity profile. The data structure may contain a plurality of values for possible battery capacity profiles, wherein values for each battery capacity profile may include a predicted increase in voltage corresponding to a temperature differential (e.g., 4 C) associated with a charging rate (e.g., 80 Amps) applied to a battery over a time duration (e.g., one minute) and based on an internal resistance (e.g., 1 milli-Ohm) of a battery having a particular battery chemistry. In some embodiments, a data structure may store, for each battery capacity profile, a battery SOC range (e.g., 10-90%) in which the values are reliable and a preferred battery SOC range (e.g., 20-80%, 30-70%, 40-60%) in which the values are more accurate. The data structure may store, for each battery capacity profile, a battery temperature range (e.g., 15-35° C.) in which the values are reliable and a preferred battery temperature range (e.g., 20-30° C., 25-30° C.) in which the values are more accurate. In other embodiments, a data structure may contain coefficients for equations for calculating a predicted voltage increase using values for a temperature differential associated with a charging rate, a time duration and an internal resistance for a battery having a particular battery chemistry. Accordingly, once vehicle 40 or operations server 10 knows the battery chemistry for a battery and charges the battery according to a selected charging rate, embodiments may determine a SOH for the battery.

Direct Current Internal Resistance (DCIR)

The DCIR of a battery depends in part, on battery chemistry and construction, depth of discharge and temperature. The DCIR of any given battery should increase at a fairly linear rate over the life of the battery. The internal resistance of a battery factors into the SOH of the battery.

Battery State of Health Effect on Battery Capacity

The SOH of a battery will generally affect the battery capacity, how quickly the battery can charge and how quickly the battery discharges. In an ideal battery, the total battery capacity never changes. When a battery is new, the battery capacity may be substantially equal to the battery capacity of the ideal battery. However, as mentioned above, the battery capacity of a battery in vehicle 40 decreases over time. As the battery capacity decreases, SOC calculations become less accurate. Thus, a battery charge capacity sensor may indicate the battery is charged to 100% SOC, but the SOH may have decreased such that the battery capacity is less. A performance plan based on the battery capacity being equal to the ideal battery capacity may cause problems. For example, a vehicle 40 operating on the assumption that the battery capacity is equal to an ideal battery capacity could underestimate its range and be forced to operate a fuel-fed engine in a zero-emissions zone (resulting in fines) or perform additional cooling, and may need to wait while the engine charges the battery, the driver adds fuel, the battery cools, or some other unexpected effect. Embodiments perform SOH testing to more accurately determine values of other operating parameters of vehicle 40.

State of Health Testing

Embodiments conduct SOH testing to assess the accuracy of the SOH of a battery in vehicle 40. SOH testing may be scheduled periodically (e.g., every month, every 5000 miles, etc.,) or based on a route (e.g., a route over 300 miles). Embodiments may test the direct current internal resistance (DCIR) to get an accurate assessment of the internal resistance of the battery, use the internal resistance in determining an increase in voltage relative to a battery temperature increase, and compare the rate at which voltage increases relative to the rate at which the battery temperature increases to estimate the battery SOC.

A SOH test may include a DCIR (direct current internal resistance) test to determine the internal resistance of a battery. A DCIR test comprises charging the battery and measuring the voltage increase. DCIR testing may comprise applying current in a set of electric pulses or other reference waveform to the battery and measuring the voltage increase. DCIR generally increases linearly over the service life of the battery. Based on the voltage increase and the current applied, the internal resistance can be calculated or determined from reference data stored in a data structure. Embodiments may determine a SOH test that includes determining the internal resistance of the battery. In some embodiments, vehicle 40 performs the calculations or performs any lookup functions in the data structure and may modify a performance plan if needed, discussed in greater detail below. In other embodiments, vehicle 40 communicates information to operations server 10, vehicle configuration server 14 to perform calculations, perform lookup functions in the data structure, modify a performance plan if needed or communicate results back to vehicle 40.

A SOH test comprises charging a battery for a time duration, measuring the battery temperature differential during the time duration, and either calculating or performing a lookup function in a data structure to determine an increase in voltage corresponding to the battery temperature differential. Embodiments may determine, for a SOH test, a charging rate (e.g., 80 Amps) and a time duration (e.g., one minute). The charging rate and time duration may be selected based on the battery, the route, the segment and vehicle 40. During the SOH test, vehicle 40 communicates with a battery temperature sensor to determine the battery temperature differential. Depending on the battery chemistry, the battery temperature differential, the internal resistance, the battery SOC and battery temperature, embodiments determine a SOH for the battery.

Embodiments described herein identify and select one or more segments in which vehicle 40 is expected to operate in a configuration for the time duration and/or prepare the battery for SOH testing. The battery SOC range and battery temperature range may be based on the battery chemistry. For example, SOH testing for Lithium-Ion batteries may be performed when the battery SOC is in the range of 20-80% but preferred in the range of 40-60% and the battery temperature is in the range of 20-35° C. but preferred in the range of 25-30° C.

State of Health Testing Only on Selected Segments

Referring back to FIG. 6, not every segment 620 is suitable for every vehicle 40 to perform SOH testing every time. Embodiments analyze segments 620 to identify a set of segments 620 for SOH testing.

Selection of Segments for SOH Testing

Embodiments may analyze all the segments in a route to identify any segments not suitable for SOH testing based on one or more vehicle characteristics. For example, if SOH testing is to be performed by vehicle 40 operating between 40-60% SOC and vehicle 40 is at 100% SOC at the start of the route, SOH testing cannot occur in the first segment. Other vehicle characteristics that may be used to filter segments include, but are not limited to, the vehicle weight, the battery temperature and the fuel level. Embodiments may also identify any segments not suitable for SOH testing based on one or more segment characteristics. For example, if a segment distance is too short, a segment grade is too steep, or there are traffic conditions that prevent vehicle 40 from operating in a SOH testing configuration for a minimum time duration, SOH testing cannot occur in the segment.

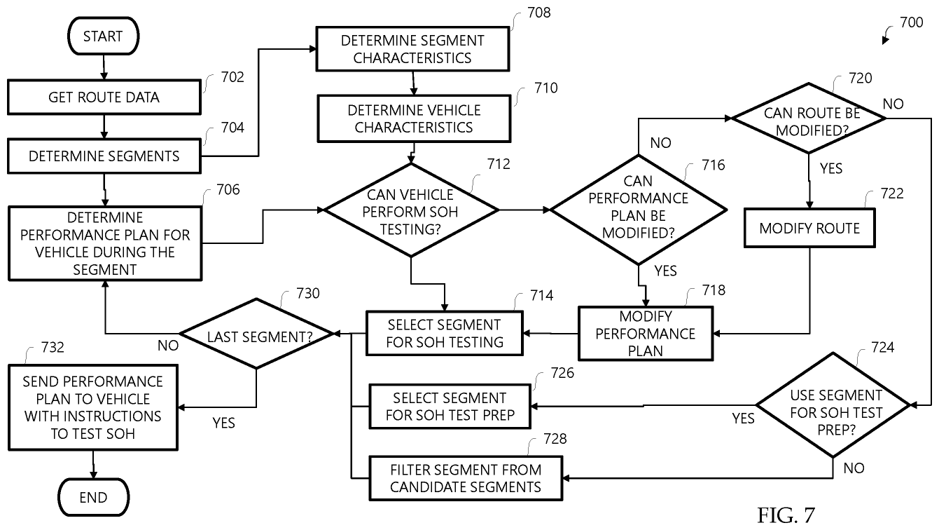

FIG. 7 depicts a flow diagram 700 of a method for identifying segments for SOH testing.

The method begins at step 702 when embodiments get route data. In some embodiments, route planning server 12 may communicate with operations server 10 to get the route data about one or more routes.

At step 704, embodiments determine segment information. In some embodiments, operations server 10 communicates with route planning server 12 to analyze route data to determine segment information.

For each segment, at step 706, embodiments determine a performance plan for vehicle 40 over the segment which includes a set of drivetrain configuration instructions and values for a set of operating parameters corresponding to the segment.

At step 708, embodiments determine segment characteristics. Segment characteristics may include information such as a grade, a distance, a road surface type and other characteristic information.

At step 710, embodiments determine vehicle characteristics. Vehicle characteristics may include information that is relatively constant such as the type of vehicle, an engine displacement, a total fuel capacity and battery chemistry, and may include variable information such as the present amount of fuel in a fuel tank, an engine efficiency, a battery SOC, a battery temperature and a battery SOH.

At step 712, embodiments determine if vehicle 40 can perform SOH testing on the segment. For example, referring to FIG. 6 and assuming SOH testing should be performed on a flat segment greater than one mile in length and when the SOC is in the preferred SOC range of 40-60% and the battery temperature is between the preferred battery temperature range of 25-30° C., SOH testing can occur only on segment SID_45 (referring to row 620-45).

Also at step 712, embodiments may determine SOH testing cannot (or should not) occur on segments SID_1, SID_2, SID_30 and SID_58 (referring to rows 620-1, 620-2, 620-30 and 620-58) because the start SOC is either greater than 60% or less than 40% and cannot (or should not) occur on segment SID_35 (referring to row 620-35) because the starting battery temperature is greater than 30 C.

At step 714, any segment in which vehicle 40 can perform SOH testing may be selected for adding to a set of SOH testing segments. A segment may be selected for SOH testing based on vehicle 40 being able to operate at steady state for a time duration necessary to complete SOH testing. Selection of a segment for SOH testing may include embodiments analyzing route data to determine a segment has a constant grade or substantially constant grade over a predetermined distance. Selection of a segment for SOH testing may also include analyzing route data to determine a segment is generally straight, has no drastic curves, turns or stops to impede vehicle 40 from operating at steady state. Selection of a segment for SOH testing may include communicating with other vehicles and/or servers over a network to determine there is no traffic, accidents, road construction or other events that would interfere with vehicle 40 operating at steady state. Steady state operation may refer to vehicle 40 traveling at a constant speed or substantially constant speed or batteries charging or discharging at a constant or substantially rate.

At step 716, embodiments determine if the performance plan can be modified such that SOH testing can occur on a segment. For example, segment SID_35 is predicted to have a start SOC of 78% and end SOC of 80%, which may be within battery SOC range limits (e.g., 20% to 80%) and the start temperature of 31° C. is within battery temperature range limits (e.g., 20-35 C). Embodiments may determine segment SID_35 could be used for SOH testing, but the SOH testing could be more accurate if the starting battery temperature was less than 30 C.

At step 718, embodiments may modify a performance plan to include drivetrain configuration instructions and values for operating parameters for additional selected segments (e.g., segment SID_35) to accommodate SOH testing and at step 714, the additional segments may be selected for SOH testing.

At step 720, if the performance plan cannot be modified, embodiments may determine if the route may be modified. For example, if SOH testing is to be performed by vehicle 40 operating in a regenerative mode (i.e., charging the battery using electric power generated by rotational power due to vehicle 40 traveling downhill), any segments with an uphill grade might be filtered from the set of SOH segments. Other segment characteristics that may be used to filter the set of segments include, but are not limited to, the length of the segment, the presence (or likelihood) of traffic on the segment, weather, road surface, curve profile and whether the segment is associated with any regulations mandating how a vehicle can operate (e.g., a “zero-emissions zone” mandating vehicles 40 cannot operate an engine that emits carbon by-products). For example, vehicle 40 traveling on segment SID_30 might not be able to perform SOH testing because the start SOC is too high and the start temperature is also too high. However, even if a performance plan could be modified to lower the start SOC and start temperature, the presence of traffic on segment SID_30 may prevent SOH testing.

At step 722, route planning server 12 may search for alternate routes to determine if more segments can accommodate SOH testing. If an alternate route is found, at step 718 embodiments may modify the performance plan based on the new route and at step 714, the additional segments may be selected for SOH testing.

At step 724, if a segment cannot be used for SOH testing, embodiments may determine if the segment may be used for preparing vehicle 40 for SOH testing. Preparing vehicle 40 for SOH testing may include cooling or warming the battery to have a starting battery temperature below a maximum battery temperature (e.g., 30° C.), greater than a minimum battery temperature (e.g., 15° C.) or within a battery temperature range (e.g., 15-30° C.). Preparing vehicle 40 for SOH testing may include charging or discharging the battery such that the starting SOC is below a maximum SOC (e.g., 80%), greater than a minimum SOC (e.g., 20%) or within a starting SOC range (e.g., 40-60% SOC). A segment may be selected for preparing vehicle 40 for SOH testing based on vehicle 40 being able to operate at steady state to achieve one or more of a battery temperature being below a maximum battery temperature and above a minimum battery temperature, a battery SOC being below a maximum battery SOC and above a minimum battery SOC. Selection of a segment for preparing vehicle 40 for SOH testing may include embodiments analyzing route data to determine a segment has a constant grade or substantially constant grade over a predetermined distance. Selection of a segment for preparing vehicle 40 for SOH testing may also include analyzing route data to determine a segment is generally straight, has no drastic curves, turns or stops to impede vehicle 40 from operating at steady state. Selection of a segment for preparing vehicle 40 for SOH testing may include communicating with other vehicles and/or servers over a network to determine there is no traffic, accidents, road construction or other events that would interfere with vehicle 40 operating at steady state. Steady state operation may refer to vehicle 40 traveling at a constant speed or substantially constant speed or batteries charging or discharging at a constant or substantially rate.

At step 726, if embodiments determine vehicle 40 can be operated in a segment to prepare vehicle 40 for SOH testing, embodiments select the segment as a prep segment.

Alternatively, at step 728, if embodiments determine vehicle 40 cannot be operated in a segment to prepare vehicle 40 for SOH testing and the route cannot be changed, embodiments filter the segment from the set of segments for SOH testing.

At step 730, embodiments determine if the segment was the last segment.

If not, then steps 706-730 may be repeated until all segments available for SOH testing are identified and selected.

If the segment was the last segment, then at step 732, embodiments communicate a performance plan to vehicle 40 with a set of drivetrain configuration instructions and values for operating parameters of the drivetrain to enable SOH testing or preparation for SOH testing on one or more selected segments. SOH testing may occur on any one or more segments. For example, embodiments may select a segment to perform all SOH testing or may select segments for each SOH test.

In some embodiments, a SOH testing segment may be selected based on a preferred SOH test. SOH tests may include measuring the internal resistance of a battery, temperature increase and/or battery capacity across one or more temperatures or temperature ranges to determine the SOH of the battery. However, in some embodiments, the SOH test may be selected based on a preferred SOH testing segment. For example, if embodiments identify only one segment for SOH testing and the vehicle 40 is expected to take only three minutes to complete the segment, embodiments may select a SOH test that requires less than three minutes to perform. If embodiments identify several segments available for SOH testing and a SOH test that requires five minutes to perform can be completed on a segment, embodiments could identify the segment that will accommodate vehicle 40 performing the five minute SOH test.

A charging rate may be any charging rate capable of triggering a measurable temperature increase in a battery over the time duration for vehicle 40. For example, for the same vehicle 40, a 60 Amp charging rate applied over five minutes may result in a battery temperature increase that can be measured accurately but the same charging rate applied over three minutes may result in a battery temperature increase that might not be measured accurately. In this scenario, embodiments may determine, for the vehicle 40 and the SOH testing segment, one or more of a higher charging rate or a longer time duration such that there is a measurable battery temperature increase. Accurately measuring a battery temperature increase may depend on the battery temperature sensor. A higher charging rate (e.g., a charging rate equal to or greater than 80 Amps) may result in temperature increases that are easier to measure accurately. Similarly, charging for very short time durations (e.g., 10 seconds) might result in no temperature increase or a temperature increase that is difficult to measure accurately. A longer time duration (e.g., greater than three minutes) may result in temperature increases that are easier to measure accurately. Accordingly, a SOH test comprises a charging rate and a time duration that will result in a measurable temperature increase in the vehicle 40 traveling on the SOH testing segment.

A prep segment may refer to more than one segment. For example, if a battery needs to be charged a significant amount and cooled, a single prep segment with a short distance might not provide vehicle 40 enough time or distance to perform both. Accordingly, a prep segment may include more than one segment.

Frequency of State of Health Testing Based on Service Life

The decrease in SOH is generally linear between 30-70% and may be generally linear between 20-80% and even 10-90% for some battery chemistries. Above 90% and below 10%, the SOH can be harder to calculate. In some embodiments, SOH testing occurs more frequently when a battery is new and tapers off once the rate at which SOH decreases becomes more linear.

In some embodiments, a vehicle 40 may have a vehicle controller configured to receive a performance plan that requires an accurate SOC. Embodiments may continually conduct SOH testing to ensure calculations based on SOC are accurate. Instead of the driver worrying if vehicle 40 will be able to travel a route distance, embodiments may perform range calculations based on an accurate SOC determined from accurate SOH values. SOH testing may be performed automatically by a controller in vehicle 40 such that no user interaction is necessary.

Information associated with the weight of a vehicle 40 may be used to manage the operating temperature and performance of a battery and an engine over a segment. For example, a vehicle controller may determine the weight of vehicle 40 is at or near a maximum weight and calculate, based on the maximum weight, how much power is needed to move vehicle 40 on a highway at a desired speed. In some embodiments, a vehicle controller may determine a weight of a vehicle 40 and calculate how much energy may be regenerated using a regenerative braking system. In some embodiments, a vehicle controller may determine the weight of a vehicle 40, analyze the route or terrain, and determine when to charge a battery or if an engine is needed to provide direct power to assist a motor/generator. In some embodiments, a vehicle controller may determine the weight of vehicle 40, analyze the route or terrain, and determine how much regenerative power is available to charge a battery including coast down charging. In some embodiments, a vehicle controller may receive an input from a driver or communicate over a network with a server to identify a route and charge a battery based on the route, including terrain on the route. In some embodiments, a vehicle controller analyzes topographical data and adjusts the performance, the state of charge (SOC) and the operating temperature of a battery and/or the performance of an engine based on the topographical data. In some embodiments, vehicle 40 includes memory storing terrain and/or route data such that SOH testing can be performed by vehicle 40 without needing to communicate over a network. In some embodiments, vehicle 40 may communicate with a GPS server or traffic server to get updated or real-time information about a route but perform all SOH testing based on a set of SOH tests stored in the memory.

A vehicle controller may also monitor system performance to determine component performance. For example, a vehicle controller may analyze power compared with vehicle speed to determine an efficiency of a motor/generator or an engine. Information may be used to determine when to service the vehicle 40 including an engine, a motor/generator, a battery, axles, a refrigerant system or a coolant system. In some embodiments, a vehicle controller may determine an ambient air temperature and calculate how much power vehicle 40 will need to cool a battery below a threshold level based on the ambient air temperature. Information may be stored in memory on vehicle 40 or communicated using a network to operations server 10 for predicting maintenance needs.

Operations server 10 may monitor operating conditions and control when charging can occur and may communicate with a driver when to plug in to a charging port, when to operate an engine and when to operate using a battery. In some embodiments, if the ambient air temperature is below a minimum temperature such that a battery is expected to perform poorly or below a minimum threshold, operations server 10 may communicate a performance plan to vehicle 40 with instructions to operate vehicle 40 such that heat is added to the battery to maintain an operating temperature of the battery above a minimum temperature threshold. In some embodiments, a vehicle controller may monitor the operating temperature of a battery and turn on an engine and open a coolant system to add heat to the battery. In some embodiments, a vehicle controller may determine vehicle 40 is in a high pollution area and operate on battery power or manage how or when an engine is used to charge the battery based on pollution levels.

In some embodiments, a vehicle controller may communicate periodically with operations server 10 to receive a performance plan or an update to a performance plan. Each time a performance plan is received, the controller is configured to use the new performance plan and store the new performance plan in memory accessible by the controller. In the event that connectivity is interrupted or the controller is unable to communicate with operations server 10, the controller may be configured to operate the vehicle 40 according to the most recent performance plan stored in memory. In some embodiments, a performance plan may be communicated to the vehicle 40 every few minutes (e.g., every five minutes) but contain a performance plan for the vehicle 40 that specifies operating parameters for a large portion of the route (e.g., 25 miles). Thus, if the vehicle 40 does not receive an update to a performance plan, the controller may still operate the vehicle 40 according to a performance plan.

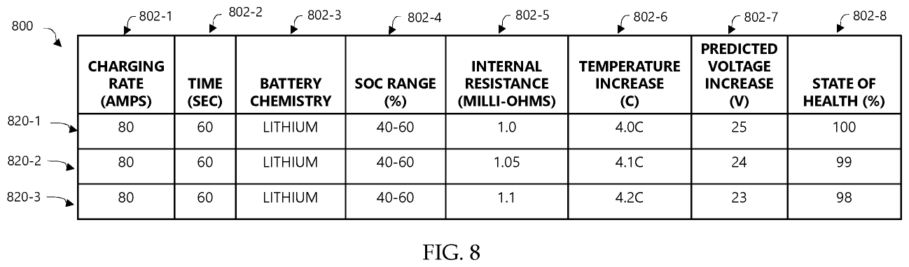

FIG. 8 depicts a data structure of values associated with battery SOH in a vehicle 40, illustrating relationships between charging rate, internal resistance, battery temperature, battery SOC, batter temperature differential and a calculated voltage increase corresponding to the stored values.

Each column 802 contains a value of an operating parameter. Some values may be selected for performing SOH testing, including charging rate 802-1 and time duration 802-2. Other values may be based on the battery being tested, including battery chemistry 802-3, SOC range 802-4 and internal resistance 802-5. Temperature increase column 802-6 contains values of a temperature differential between the battery temperature measured at the start of the time duration and the battery temperature measured at the end of the time duration. Predicted voltage increase column 802-7 contains voltage increase values calculated based on previous tests. SOH column 802-8 contains values for SOH based on the relationship between temperature increase and the voltage increase. For example, referring to row 820-1, for a charging rate (e.g., 80 A) applied for a time duration (e.g., 60 seconds) to a battery having a battery chemistry (e.g., Lithium ion such as LFP, NMC, LTO, or the like) with a starting battery SOC between 40-60% and an internal resistance (e.g., 1 milli-ohm) results in a temperature increase (e.g. 4.0° C.). The temperature increase may correspond to a 25V increase in voltage, which relates to 100% SOH for a battery SOC between 40-60%. As the internal resistance increases, the temperature differential increases for the same testing conditions, resulting in a lower SOH, as depicted in rows 820-2 and 820-3.

Data structure 800 may include tables for other testing conditions (e.g., battery SOC between 20-80%), charging rates (e.g., 85 A, 90 A), other time durations and other battery chemistries, for example. Embodiments may select the charging rate, time duration and other testing conditions based on vehicle characteristics and/or segment characteristics.

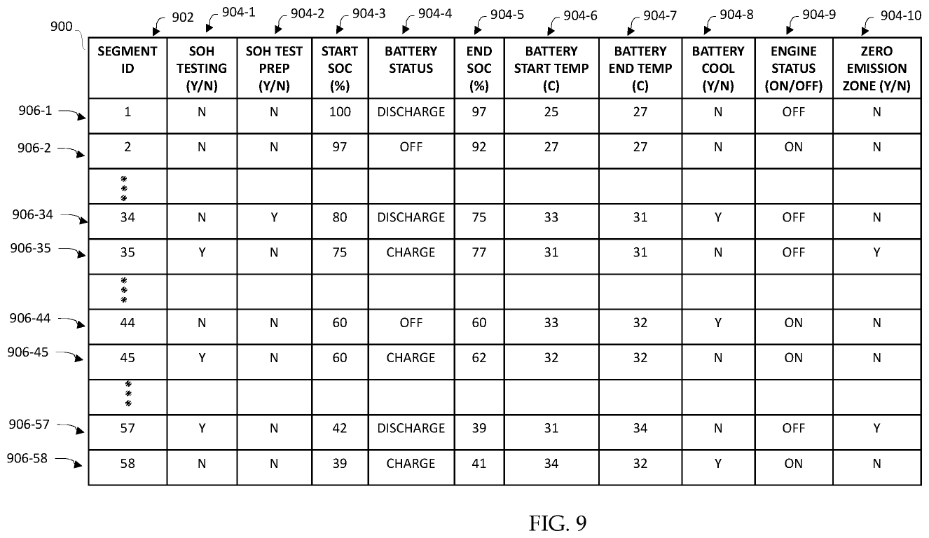

FIG. 9 depicts a data structure 900 containing a portion of a performance plan for vehicle 40, including a set of drivetrain configuration instruction and values for operating parameters of vehicle 40 for SOH testing along the route. Column 902 contains a segment identifier (which corresponds to a segment for the route as described above). Column 904-1 contains information regarding whether SOH testing can occur on the segment. Column 904-2 contains information regarding whether SOH test preparation can occur on the segment. Column 904-3 contains a value of the starting battery SOC for the segment. At the start of the route, for the first segment, the value for the starting battery SOC may be a measured value and the values for other segments may be predicted or target values. As vehicle 40 travels along the route, the value may be updated to reflect actual values. Column 904-4 contains information regarding whether the battery should be charged or discharged on the segment. Column 904-5 contains a value of the end battery SOC for the segment. Column 904-6 contains a value of the starting battery temperature for the segment. Column 904-7 contains a value of the end battery temperature for the segment. Column 904-8 contains information regarding whether the battery should be cooled on the segment. Column 904-9 contains information regarding whether the engine should be turned on or turned off on the segment. Column 904-10 contains information regarding whether the segment is part of a zero emissions zone.

A performance plan communicated to a vehicle 40 may include information contained in data structure 900 to ensure vehicle 40 completes the route, including performing SOH testing. The values of operating parameters of vehicle 40 may be monitored and the performance plan may be modified as needed to accommodate variations in the operating parameters.

The above disclosed subject matter is to be considered illustrative, and not restrictive, and the appended claims are intended to cover all such modifications, enhancements, and other embodiments which fall within the true spirit and scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A method for monitoring state of health (SOH) of a battery in a vehicle, comprising:
determining a route for the vehicle to travel;
selecting a SOH testing segment on the route, the SOH testing segment having a distance and a grade;
selecting a SOH test comprising a charging rate for supplying electric power to the battery or a discharging rate for supplying electric power from the battery and a time duration for supplying the electric power to or from the battery;
selectively operating a motor/generator (M/G) as a generator to supply the electric power to the battery at the charging rate for the time duration or as a motor operating on electric power supplied from the battery at the discharging rate as the vehicle travels along the SOH testing segment; and
determining a change in an internal resistance, a temperature, a voltage, a SOC, or a combination thereof based on the charging rate or discharging rate of the battery to determine the SOH of the battery.

2. The method of claim 1, wherein determining the state of health of the battery comprises:
measuring a starting battery temperature at the start of the time duration;
operating the M/G as a generator to supply the electric power to the battery at the charging rate or operating the M/G as a motor using the electric power supplied from the battery for the time duration;
measuring an end battery temperature at the end of the time duration;
calculating a battery temperature differential for the time duration;
determining a voltage increase or a voltage decrease based on the battery temperature differential and the SOC of the battery; and
determining the state of health of the battery corresponding to the voltage increase or voltage decrease and the SOC of the battery.

3. The method of claim 1, further comprising:
storing, in memory, a data structure comprising a plurality of battery capacity profile tables, wherein each battery capacity profile table contains stored values for one of a battery charging rate or a battery discharging rate, an internal resistance of the battery, a SOC of the battery and a battery temperature differential and a calculated voltage increase corresponding to the stored values; and
comparing the supplied charging rate or discharging rate, the measured internal resistance of the battery, the calculated battery temperature differential, and the SOC of the battery with the stored values in a battery capacity profile table of the plurality of battery capacity profile tables to determine the voltage increase or voltage decrease based on the calculated voltage increase or voltage decrease contained in the battery capacity profile table of the plurality of battery capacity profile tables.

4. The method of claim 3, wherein measuring the internal resistance of the battery comprises:
operating the M/G as a generator for generating electric power;
supplying the electric power to the battery according to a reference waveform;
measuring the voltage increase;
calculating the internal resistance of the battery based on the voltage increase for the reference waveform; and
storing the internal resistance of the battery in the memory.

5. The method of claim 4, wherein the reference waveform comprises a series of pulses of the supplied electric power.

6. The method of claim 1, wherein the SOH test comprises a constant charging rate or discharging rate.

7. The method of claim 1, further comprising:
determining a prep segment preceding the SOH testing segment; and
operating the vehicle in the prep segment to perform one of:
cooling the battery, whereby the starting battery temperature is less than a maximum SOH testing battery temperature;
warming the battery, whereby the starting battery temperature is greater than a minimum SOH testing battery temperature;
charging the battery, whereby the battery SOC is greater than a minimum SOH testing battery SOC; and
discharging the battery, whereby the battery SOC is less than a maximum SOH testing battery SOC.

8. The method of claim 1, wherein selecting a SOH testing segment on the route comprises:
receiving a set of route data corresponding to the route;
determining a route start point and a route end point for the set of route data;
identifying a plurality of segments, comprising:
identifying a set of uphill segments in the route data, wherein each uphill segment is defined by a grade that exceeds a minimum grade threshold and a segment distance that is greater than a defined minimum distance;
identifying a set of downhill segments in the route data, wherein each downhill segment is defined by an average grade that is less than a defined downhill threshold and a segment distance that is greater than the defined minimum distance; and
identifying a set of flat segments in the route data, wherein each flat segment is defined as a segment determined to not be an uphill segment or a downhill segment and a segment distance that is greater than a defined minimum distance; and
selecting the SOH testing segment from the plurality of segments based on a set of vehicle characteristics and a set of segment characteristics.

9. The method of claim 8, wherein selecting a SOH testing segment based on a set of vehicle characteristics and a set of segment characteristics comprises:
determining a performance plan for the vehicle, the performance plan comprising a set of drivetrain configuration instructions and values of a set of operating parameters of the vehicle for each segment of the plurality of segments, wherein the values comprise a starting battery SOC range and a starting battery temperature range;
for each segment:
calculating a predicted starting battery SOC, wherein selecting the SOH testing segment comprises determining a segment of the plurality of segments with a predicted starting battery SOC in the starting battery SOC range;
calculating a predicted starting battery temperature, wherein selecting the SOH testing segment comprises determining a segment of the plurality of segments with a predicted starting battery temperature in the starting battery temperature range;
determining a segment distance, wherein selecting the SOH testing segment comprises determining a segment of the plurality of segments with a segment distance greater than a minimum SOH testing distance; and
determining a grade, wherein selecting the SOH testing segment comprises determining a segment of the plurality of segments with a grade that does not exceed a minimum SOH testing grade or a maximum SOH testing grade.

10. The method of claim 9, wherein the starting battery SOC range is between 20% and 80% and the starting battery temperature range is between 20-35 C.

11. The method of claim 9, wherein the starting battery SOC range is between 40% and 60% and the starting battery temperature range is between 25-30 C.

12. A system for determining state of health (SOH) for a battery on a vehicle, the system comprising:
a server storing instructions that are configured when executed by the server to:
determine a route between a route start point and a route end point for a vehicle;
determine a plurality of segments between the route start point and the route end point, each segment comprising a grade and a distance;
select a SOH testing segment from the plurality of segments;
select a SOH test comprising a charging rate for supplying electric power to the battery or a discharging rate for drawing electric power from the battery and a time duration for supplying the electric power or drawing the electric power; and
communicate information comprising the SOH test and the SOH testing segment to the vehicle; and
a controller in the vehicle storing instructions that are configured when executed by the controller to:
receive the SOH test and the SOH testing segment;
selectively operate a motor/generator (M/G) as a generator to supply the electric power to the battery at the charging rate or as a motor to draw the electric power from the battery at the discharging rate for the time duration as the vehicle travels along the SOH testing segment; and
determine a change in internal resistance, a temperature, a voltage and a SOC, or a combination thereof based on the charging rate or discharging rate of the battery to determine the SOH of the battery.

13. The system of claim 12, wherein the controller on the vehicle stores instructions that are configured when executed by the controller to:
measure an internal resistance of the battery;
measure a starting battery temperature at the start of the time duration;
operate the M/G as a generator to supply the electric power to the battery at the charging rate or operate the M/G as a motor to receive the electric power from the battery at the discharging rate for the time duration; and
measure an end battery temperature at the end of the time duration; and
communicate the measured internal resistance, the starting battery temperature and the end battery temperature to the server,
wherein the server stores instructions that are configured when executed by the server to:
calculate a battery temperature differential for the time duration; and
determine a voltage increase or a voltage decrease based on the battery temperature differential; and
determine a SOH of the battery corresponding to the voltage increase or the voltage decrease and the battery temperature differential.

14. The system of claim 12, further comprising:
a memory storing a data structure comprising a plurality of battery capacity profile tables, wherein each battery capacity profile table contains stored values for a charging rate, an internal resistance of the battery, a SOC of the battery, a battery temperature differential and a calculated voltage increase corresponding to the stored values; and
the server stores instructions that are configured when executed by the server to:
compare the supplied charging rate, the measured internal resistance of the battery, the calculated battery temperature differential, and the measured SOC of the battery with the stored values for the charging rate, the internal resistance of the battery, the battery temperature differential and the starting battery SOC in a battery capacity profile table of the plurality of battery capacity profile tables to determine the voltage increase based on the calculated voltage increase contained in the battery capacity profile table from the plurality of battery capacity profile tables.

15. The system of claim 14, wherein the controller on the vehicle stores instructions that are configured when executed by the controller to:
operate the M/G as a generator for generating electric power;
supply the electric power to the battery according to a reference waveform;
measure the voltage increase;
calculate the internal resistance of the battery based on the measured voltage increase for the reference waveform; and
communicate a value for the internal resistance of the battery to the server.

16. The system of claim 14, wherein the reference waveform comprises a series of pulses of the supplied electric power.

17. The system of claim 12, wherein the SOH test comprises a constant charging rate.

18. The system of claim 12, wherein:
the server further stores instructions that are configured when executed by the server to determine a prep segment preceding the SOH testing segment; and
the controller further stores instructions that are configured when executed by the controller to perform, when the vehicle is in the prep segment, one or more of:
cooling the battery, whereby the starting battery temperature is less than a maximum SOH testing battery temperature;
warming the battery, whereby the starting battery temperature is greater than a minimum SOH testing battery temperature;
charging the battery, whereby the battery SOC is greater than a minimum SOH testing battery SOC; and
discharging the battery, whereby the battery SOC is less than a maximum SOH testing battery SOC.

19. The system of claim 12, wherein the server further stores instructions that are configured when executed by the server to:
identify a set of uphill segments in the route data, wherein each uphill segment is defined by a grade that exceeds a minimum grade threshold and a segment distance that is greater than a defined minimum distance;
identify a set of downhill segments in the route data, wherein each downhill segment is defined by an average grade that is less than a defined downhill threshold and a segment distance that is greater than the defined minimum distance; and
identify a set of flat segments in the route data, wherein each flat segment is defined as a segment determined to not be an uphill segment or a downhill segment and a segment distance that is greater than a defined minimum distance; and
select a SOH testing segment from the plurality of segments based on a set of vehicle characteristics and a set of segment characteristics.

20. The system of claim 19, wherein to select a SOH testing segment based on a set of vehicle characteristics and a set of segment characteristics, the server stores instructions that are configured when executed by the server to:
determine a performance plan for the vehicle, the performance plan comprising a set of drivetrain configuration instructions and values of a set of operating parameters of the vehicle for each segment of the plurality of segments, wherein the values comprise a starting battery SOC range and a starting battery temperature range;
for each segment:
calculate a predicted starting battery SOC, wherein the server executes instructions to select the SOH testing segment with the predicted starting battery SOC in the starting battery SOC range;
calculate a predicted starting battery temperature, wherein the server executes instructions to select the SOH testing segment with the predicted starting battery temperature in a starting battery temperature range;
determine a segment distance, wherein the server executes instructions to select the SOH testing segment with a segment distance greater than a minimum SOH testing distance; and
determine a grade, wherein the server executes instructions to select the SOH testing segment with a grade that does not exceed a minimum SOH testing grade or a maximum SOH testing grade.

21. The system of claim 20, wherein the starting battery SOC range is between 20% and 80% and the starting battery temperature range is between 20-35 C.

22. The system of claim 20, wherein the starting battery SOC range is between 40% and 60% and the starting battery temperature range is between 25-30 C.
